(19) United States
(12) Patent Application Publication
(10) Pub. No.: US 2021/0351115 A1
(43) Pub. Date: Nov. 11, 2021

(54) ELECTRONIC DEVICE

(71) Applicant: FUJITSU LIMITED, Kawasaki-shi (JP)

(72) Inventor: Tetsuya Takahashi, Nagano (JP)

(73) Assignee: FUJITSU LIMITED, Kawasaki-shi (JP)

(21) Appl. No.: 17/166,305

(22) Filed: Feb. 3, 2021

(30) Foreign Application Priority Data
May 7, 2020 (JP) 2020-082259

(51) Int. Cl. H01L 23/498; H01L 23/00

(52) U.S. Cl. CPC H01L 23/49811; H01L 2224/08225; H01L 23/49838; H01L 24/08

(57) ABSTRACT

An electronic device includes a mounting substrate; a package arranged facing the mounting substrate; a plurality of first pads arranged on a facing surface facing the mounting substrate along a long side of the facing surface in the package; a plurality of second pads arranged on the facing surface at respective corners of the facing surface; a plurality of first lands provided on the mounting substrate and electrically bonded to the plurality of first pads, respectively facing the plurality of first pads; and a plurality of second lands provided on the mounting substrate and electrically bonded to the plurality of second pads, respectively facing the plurality of second pads.

### CROSS-REFERENCE TO RELATED APPLICATION

This application is based upon and claims the benefit of priority of the prior Japanese Patent Application No. 2020-82259, filed on May 7, 2020, the entire contents of which are incorporated herein by reference.

### FIELD

The technology disclosed in the present application relates to an electronic device.

### BACKGROUND

There have been substrates each including a base and a plurality of externally mounting terminals formed on a lower surface of the base and bonded to a mounting substrate via solder.

In this substrate, the plurality of externally mounting terminals includes sub-electrode terminals. When a circle circumscribing the sub-electrode terminals is defined in plan view of the base, all of the externally mounting terminals are included in the circle, and circular tangent parts, which are parts in contact with the circle, of the sub-electrode terminals, extend along a circumference and are provided facing each other through a center of the circle. For example, Japanese Laid-open Patent Publication No. 2013-033821 is disclosed.

### SUMMARY

According to an aspect of the embodiments, an electronic device includes a mounting substrate; a package arranged facing the mounting substrate; a plurality of first pads arranged on a facing surface facing the mounting substrate along a long side of the facing surface in the package; a plurality of second pads arranged on the facing surface at respective corners of the facing surface; a plurality of first lands provided on the mounting substrate and electrically bonded to the plurality of first pads, respectively facing the plurality of first pads; and a plurality of second lands provided on the mounting substrate and electrically bonded to the plurality of second pads, respectively facing the plurality of second pads.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view illustrating a substrate unit of a first embodiment;

FIG. 2 is an enlarged cross-sectional view illustrating the substrate unit of the first embodiment in part D in FIG. 1;

FIG. 3 is a plan view illustrating a package of the substrate unit of the first embodiment;

FIG. 4 is an enlarged plan view illustrating the package of the substrate unit of the first embodiment in the vicinity of a corner;

FIG. 5 is a plan view illustrating a mounting substrate of the substrate unit of the first embodiment;

FIG. 6 is an enlarged plan view illustrating the mounting substrate of the substrate unit of the first embodiment in the vicinity of a corner;

FIG. 7 is a plan view illustrating a package of a substrate unit of a comparative example;

FIG. 8 is an enlarged plan view illustrating the package of the substrate unit of the comparative example in the vicinity of a corner;

FIG. 9 is a cross-sectional view illustrating a state in which an impact acts on the substrate unit of the comparative example;

FIG. 10 is a partially enlarged cross-sectional view illustrating the state in which an impact acts on the substrate unit of the comparative example;

FIG. 11 is a partially enlarged cross-sectional view illustrating a state in which an impact acts on the substrate unit of the first embodiment;

FIG. 12 is a front view illustrating a test jig for an impact drop test on the substrate unit together with the substrate unit;

FIG. 13 is a graph illustrating a relationship between a radius of curvature of a curved part and life magnification of the substrate unit;

FIG. 14 is an enlarged plan view illustrating a mounting substrate of a substrate unit of a first modification in the vicinity of a corner;

FIG. 15 is an enlarged plan view illustrating a mounting substrate of a substrate unit of a second modification in the vicinity of a corner;

FIG. 16 is an enlarged plan view illustrating a mounting substrate of a substrate unit of a third modification in the vicinity of a corner;

FIG. 17 is an enlarged plan view illustrating a mounting substrate of a substrate unit of a fourth modification in the vicinity of a corner;

FIG. 18 is an enlarged plan view illustrating a mounting substrate of a substrate unit of a fifth modification in the vicinity of a corner; and

FIG. 19 is a plan view illustrating a mounting substrate of a substrate unit of a second embodiment.

### DESCRIPTION OF EMBODIMENTS

However, in a substrate unit having a package such as a land grid array (LGA) package mounted on a mounting substrate, bending rigidity of a part where the package is mounted is high whereas bending rigidity of a part where the package is not mounted is relatively low. That is, the bending rigidity abruptly changes at a boundary between the portion where the package is mounted and the portion where the package is not mounted.

In the case where an impact acts on such the substrate unit, a stress may be concentrated at the boundary portion of the bending rigidity and a strain may occur.

In view of the foregoing, it is desirable to suppress the strain due to the stress concentration at the time of action of the impact in the substrate unit having the package mounted on the mounting substrate.

A substrate unit 102 of a first embodiment will be described in detail with reference to the drawings.

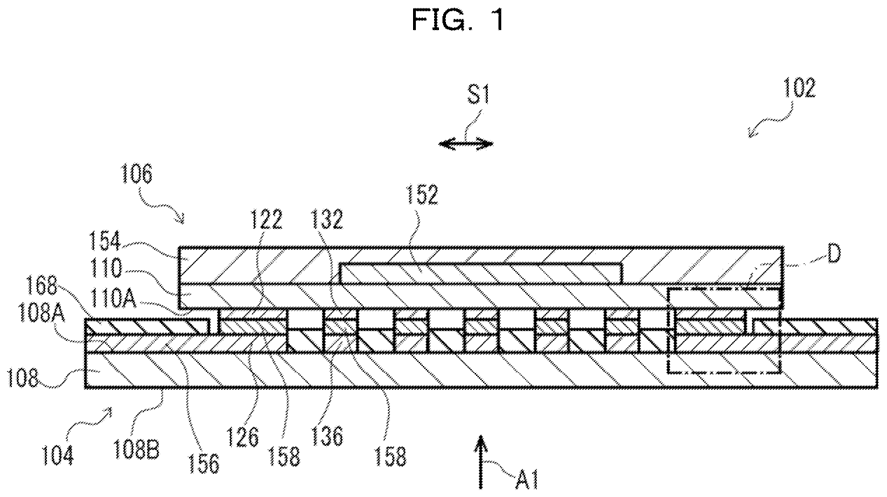

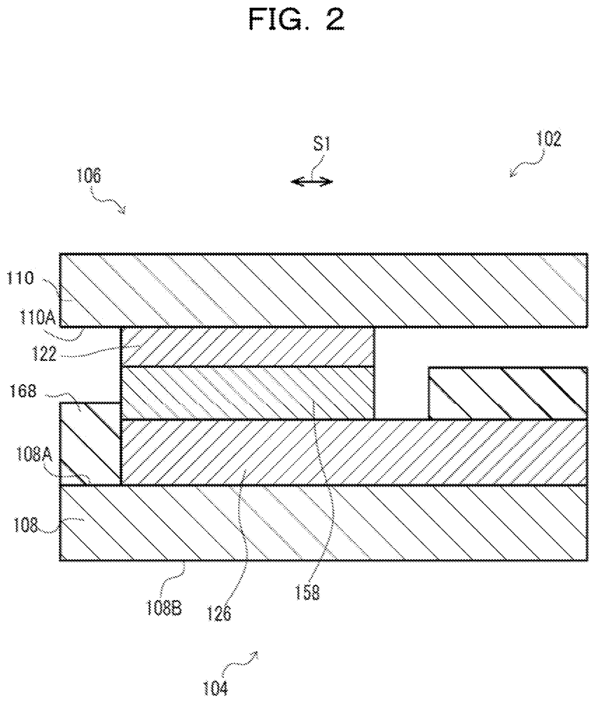

As illustrated in FIGS. 1 and 2, the substrate unit 102 includes a mounting substrate 104 and an LGA package 106.

In the example illustrated in FIG. 1, the mounting substrate 104 has a plate-shaped base material 108 having rigidity and non-conductivity. An upper surface of the base material 108 in FIG. 1 is a first surface 108A and a lower surface is a second surface 108B, but an up-down direction when the substrate unit 102 is used is not particularly limited. In the example illustrated in FIG. 1, the LGA package 106 is arranged on the first surface 108A side of the mounting substrate 104.

The LGA package 106 has a plate-shaped package substrate 110 having rigidity and non-conductivity. In the package substrate 110, a surface facing the mounting substrate 104 is a facing surface 110A. The package substrate 110 has a rectangular shape having a long side 110L and a short side 1105 when viewed in a normal direction (an arrow A1 direction) of the facing surface 110A. Hereinafter, the term “normal direction” simply refers to the normal direction of the facing surface 110A.

In the present embodiment, the package substrate 110 is rectangular when viewed in the normal direction, and has a pair of long sides 110L and a pair of short sides 1105. In the drawings, the direction of the long side 110L is illustrated by an arrow L1, and the direction of the short side 110S is illustrated by an arrow S1, respectively.

This rectangle also includes a square with the same four sides in length. In this case, any pair of parallel facing sides may be the long sides, and the two sides orthogonal to the long sides may be the short sides.

A plurality of first pads 112, a plurality of second pads 122, and a plurality of third pads 132 are provided on the facing surface 110A of the package substrate 110. The first pad 112, the second pad 122, and the third pad 132 are all formed using a conductive member such as copper foil.

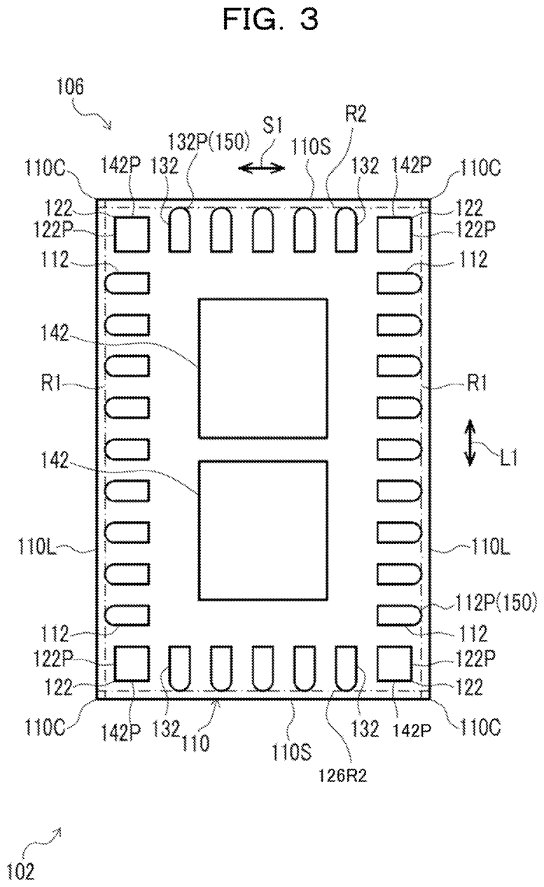

As illustrated in FIG. 3, the plurality of first pads 112 is arranged at regular intervals along each of the two long sides 110L of the package substrate 110. In the example illustrated in FIG. 3, nine first pads 112 are provided per one long side 110L, and eighteen first pads 112 are provided in the entire package substrate 110. However, the number of first pads 112 per one long side 110L is not limited as long as there is a plurality of first pads.

The plurality of second pads 122 is arranged corresponding to four corners 110C of the package substrate 110. In the example illustrated in FIG. 3, one second pad 122 is provided at each corner 110C, and four second pads 122 are provided in the entire package substrate 110.

The plurality of third pads 132 is arranged at regular intervals along each of the two short sides 110S of the package substrate 110. In the example illustrated in FIG. 3, five third pads 132 are provided per one short side 110S, and ten third pads 132 are provided in the entire package substrate 110. However, the number of third pads 132 per one short side 110S is not limited.

In each of the long sides 110L, the first pads 112 are arranged side by side along the long side 110L between the second pads 122 located at the corners 110C at both ends of the long side 110L. Furthermore, in each of the short sides 110S, the third pads 132 are arranged side by side along the short side 110S between the second pads 122 located at the corners 110C at both ends of the short side 110S.

A fourth pad 142 is arranged in a central portion of the package substrate 110. In the example illustrated in FIG. 3, the fourth pad 142 has a substantially square shape larger than the first pad 112, the second pad 122, and the third pad 132, but the shape of the fourth pad 142 is not limited. Furthermore, the number of fourth pads 142 is not limited.

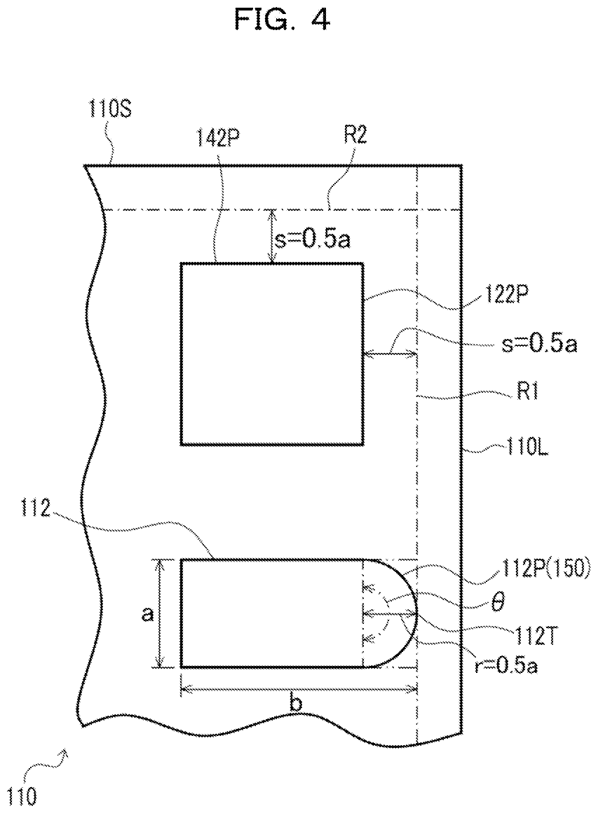

The shape of the first pad 112 is substantially rectangular when viewed in the normal direction. Here, as illustrated in FIG. 4, in each of the first pads 112, a portion located on the long side 110L side of the package substrate 110 is referred to as a first outer part 112P. The first outer part 112P is a curved part 150 having a curved shape in the example illustrated in FIG. 4. That is, the first pad 112 has a shape in which the first outer part 112P located on the long side 110L side is not linear but is curved outward (toward the long side 110L).

In the present embodiment, in the example illustrated in FIG. 4, the curved part 150 is curved with a fixed radius of curvature r. In the first pad 112, a length in a direction along the long side 110L of the package substrate 110 is a, and a length in a direction along the short side 110S is b. At this time, the radius of curvature r of the curved part 150 is an arc shape with r=0.5 a in the example illustrated in FIG. 4. Furthermore, a central angle θ of the arc of the curved part 150 is 180 degrees.

In each of the plurality of first pads 112, the position of an end 112T, that is, an end part on the long side 110L side is fixed. Assuming that a line connecting the ends 112T of the plurality of first pads 112 is a first reference line R1, the position of the end 112T of any of the first pads 112 is the position of the first reference line R1 (a point on the first reference line R1). The first reference line R1 is parallel to the long side 110L.

Then, a first land 116 has a structure provided with an inner displacement part located inside the end 112T by setting each first outer part 112P as the curved part 150. That is, in the first embodiment, the curved part 150 is an example of the inner displacement part.

In the present embodiment, the shape of the second pad 122 is substantially square when viewed in the normal direction. Here, in each of the second pads 122, a portion located on the long side 110L side of the package substrate 110 is referred to as a second outer part 122P. In the example illustrated in FIG. 4, the second outer part 122P is located inside the first reference line R1. That is, the second pad 122 has a linear side parallel to the first reference line R1 on the long side 110L side and is offset inward with respect to the first reference line R1.

In the example illustrated in FIG. 4, the second outer part 122P is offset by a fixed offset amount s, and specifically, the offset amount s=0.5 a.

In the example illustrated in FIG. 3, the shape of the third pad 132 is substantially rectangular when viewed in the normal direction. Here, in each of the third pads 132, a portion located on the short side 1105 side of the package substrate 110 is referred to as a third outer part 132P. In the example illustrated in FIG. 3, the third outer part 132P is a curved part 150 having a curved shape similarly to the first outer part 112P. That is, the third pad 132 has a shape in which the third outer part 132P located on the short side 1105 side is not linear but is curved outward (toward the short side 1105).

In the example illustrated in FIG. 3, the curved part 150 of the third pad 132 is curved with a fixed radius of curvature r, similarly to the curved part 150 of the first pad 112. In the third pad 132, the length in the direction along the short side 110S of the package substrate 110 is a, the length in the direction along the long side 110L is b, the radius of curvature r of the curved part 150=0.5 a, the central angle θ of the arc of the curved part 150 is 180 degrees.

In each of the plurality of third pads 132, the position of the end 112T, that is, the end part on the short side 110S side is fixed. Assuming that a line connecting the ends 112T of the plurality of third pads 132 is a second reference line R2, the position of the end 112T of any of the third pads 132 is the position of the second reference line R2 (a point on the second reference line R2). The second reference line R2 is parallel to the short side 1105.

In each of the second pads 122, a portion located on the short side 110S side of the package substrate 110 is referred to as a fourth outer part 142P. In the example illustrated in FIG. 3, the fourth outer part 142P is located inside the second reference line R2. That is, the second pad 122 has a linear side parallel to the second reference line R2 on the short side 110S side and is offset inward with respect to the second reference line R2. In the example illustrated in FIG. 3, the fourth outer part 142P is offset by the fixed offset amount s=0.5 a.

In the package substrate 110, a surface opposite to the facing surface 110A is a mounting surface 1108. A chip 152 is mounted on the mounting surface 1108. The chip 152 is, for example, a main body portion of an integrated circuit or the like. Then, the entire mounting surface 110B is covered including the chip 152 by a mold 154 provided on the package substrate 110. The mold 154 protects the chip 152 and increases the bending rigidity of the package substrate 110.

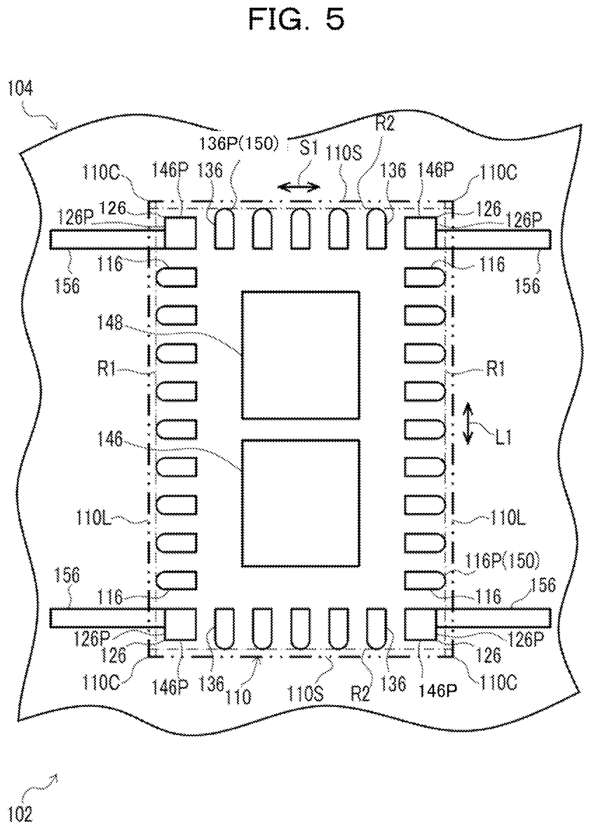

As illustrated in FIG. 5, the mounting substrate 104 is provided with the first land 116, a second land 126, and a third land 136.

When viewed in the normal direction (the arrow A1 direction) of the facing surface 110A, the first pad 112 and the first land 116 have the same shape, the second pad 122 and the second land 126 have the same shape, and the third pad 132 and the third land 136 have the same shape.

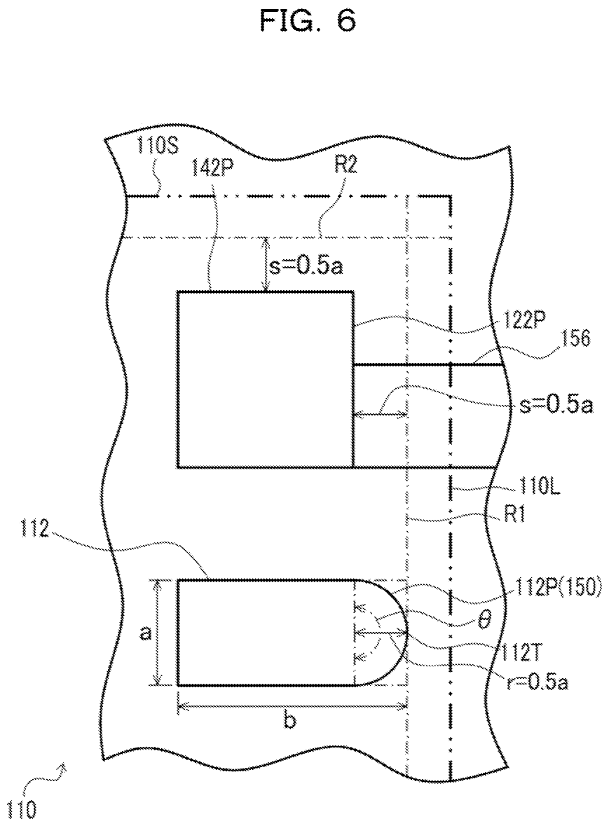

That is, as illustrated in FIG. 6, the first land 116 is also provided with the curved part 150 on the first outer part 116P. Each end 116T of the first land 116 is located at the first reference line R1, and the first outer part 116P is provided with the curved part 150. In the state where the LGA package 106 is mounted at a predetermined position on the mounting substrate 104, the first pad 112 and the first land 116 overlap each other when viewed in the normal direction of the facing surface 110A.

Furthermore, the second pad 122 and the second land 126 have the same shape when viewed in the normal direction (arrow A1 direction) of the facing surface 110A. A second outer part 126P of the second land 126 is also a portion offset inward with the fixed offset amount s.

The third pad 132 and the third land 136 have the same shape when viewed in the normal direction (direction of arrow A1) of the facing surface 110A. The third land 136 is also provided with the curved part 150 on a third outer part 136P.

In the state where the LGA package 106 is mounted on the mounting substrate 104, the first pad 112 and the first land 116 face each other, the second pad 122 and the second land 126 face each other, and the third pad 132 and the third land 136 face each other. These lands and pads are bonded by solder 158 and electrically connected. The present embodiment adopts the LGA structure, and thin film-like solder is applied between the land and the pad. However, a ball grid array (BGA) structure using ball-like solder may be adopted.

Wiring 156 is continuously provided from the second land 126 in each of the second lands 126. The wiring 156 is a member having conductivity and extending in the direction along the short side 110S. The substrate unit 102 is electrically connected to external electronic components and electronic devices by using the wiring 156.

In the mounting substrate 104, the portion where the above-described land is not provided is covered with a resist 168.

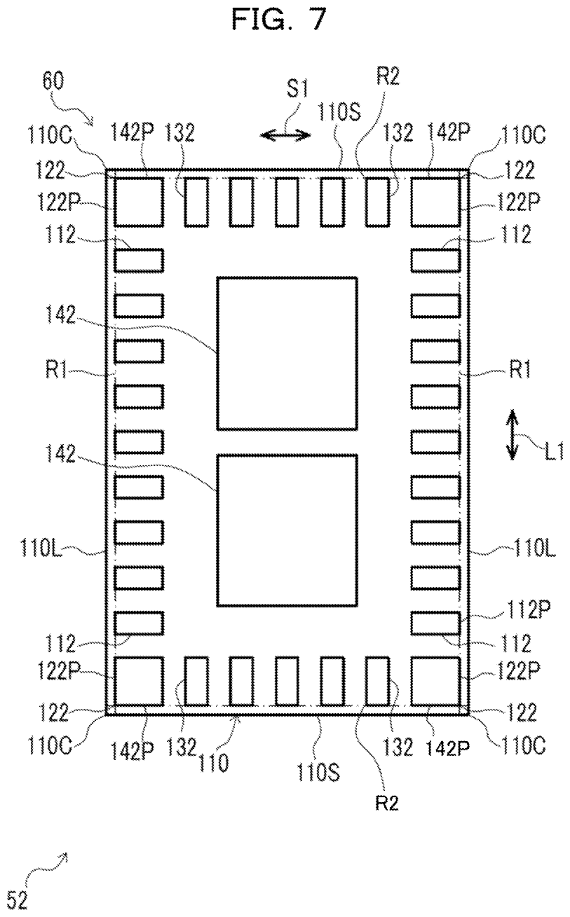

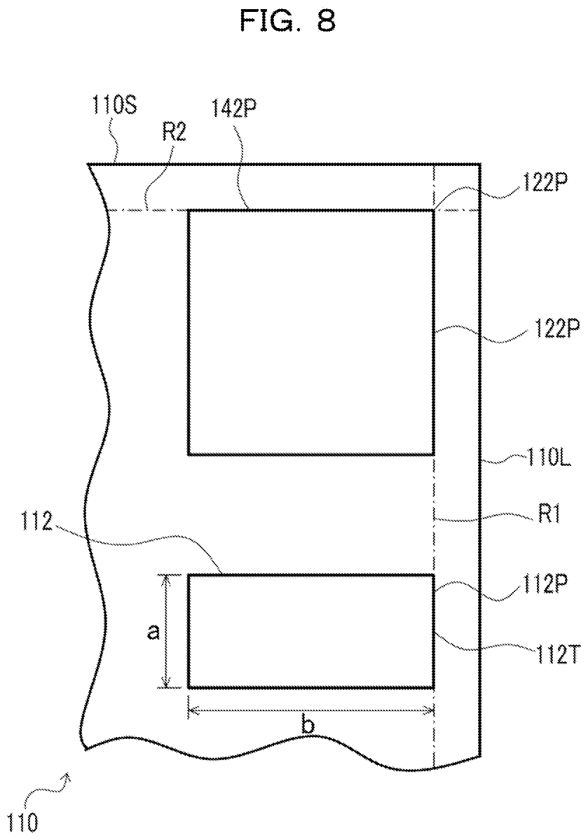

Next, the operation of the present embodiment will be described in comparison with a substrate unit 52 of a comparative example illustrated in FIGS. 7 to 10.

In a package substrate 60 of the substrate unit 52 of the comparative example, each of the plurality of first pads 112 is not provided with the curved part 150 (see FIG. 3), as illustrated in FIG. 7. That is, the first outer part 112P of the first pad 112 is a linear side located at the position corresponding to the first reference line R1. Furthermore, the curved part 150 is also not provided in each of a plurality of first lands (not illustrated) of a mounting substrate 54 of the comparative example. That is, the first outer part of the first land according to the comparative example is a linear side located at the position corresponding to the first reference line R1.

Moreover, in the package substrate 60 of the comparative example, the second outer part 122P is located at the same position as the second reference line R2 in each of the plurality of second pads 122, and the second outer part is located at the same position as the first reference line R1 in each of the plurality of second lands (not illustrated) of the mounting substrate 54 of the comparative example.

In addition, in the package substrate 60 of the comparative example, the curved part 150 (see FIG. 3) is not provided in each of the plurality of third pads 132, and the curved part 150 is not provided in each of the third lands (not illustrated) of the mounting substrate 54 of the comparative example.

In both the mounting substrate 104 of the first embodiment and the mounting substrate of the comparative example, the portion where the first land 116 and the second land 126 are provided has higher bending rigidity of the mounting substrate 104 than the portion where the first land 116 and the second land 126 are not provided. Then, in the package substrate 60 of the comparative example, the first outer part is linear and located at the same position as the first reference line R1 in each of the first lands, and the second outer part is located at the same position as the first reference line R1 in each of the second lands. In particular, since the bending rigidity of the package substrate 110 is higher in the direction (arrow S1 direction) of the short side 110S than in the direction (arrow L1 direction) of the long side 110L, the bending rigidity in the arrow S1 direction is higher than the bending rigidity in the arrow L1 direction even in the mounting substrate 104 of the portion where the package substrate 110 is mounted.

Thereby, in the mounting substrate 54 of the comparative example, the bending rigidity abruptly changes at the first reference line R1 as the boundary. Therefore, for example, when vibration in a plate thickness direction repeatedly acts on the mounting substrate 54, the stress is concentrated at the position of the first reference line R1. For example, in the case where an electronic device equipped with the substrate unit is mounted on a vehicle such as an automobile, the stress tends to be concentrated at the position of the first reference line R1 due to continuous vibration.

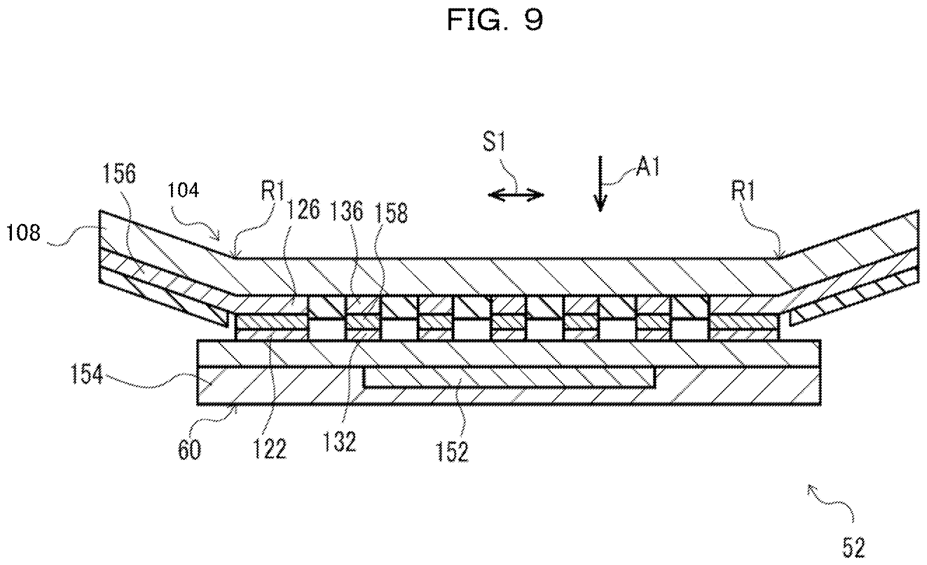

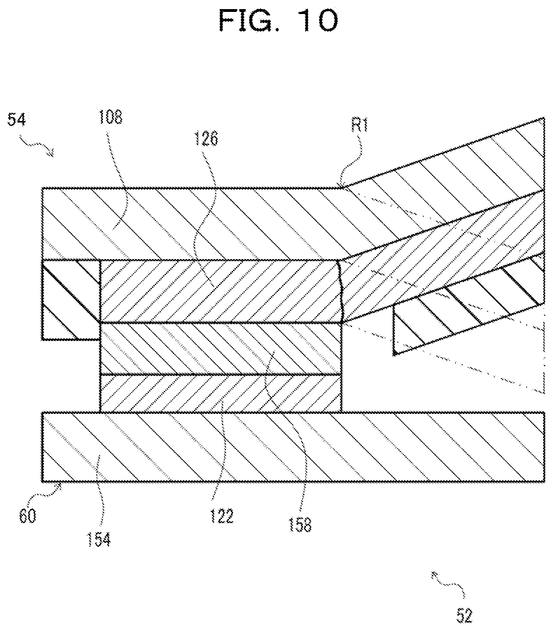

In such a mounting substrate 54 of the comparative example, bending occurs at the position of the first reference line R1 and the strain becomes large, as illustrated in FIGS. 9 and 10. Since the wiring 156 crosses the first reference line R1, the wiring 156 may be broken (disconnected) due to fatigue if plastic strain is accumulated in the wiring 156.

In contrast, in the substrate unit 102 of the first embodiment, the curved part 150 is provided in the first outer part 112P of the first land 116, and the first outer part 112P is also the inner displacement part located inside the first reference line R1 except for the end 112T. Furthermore, the second outer part 122P of the second land 126 is also a second displacement part located inside the first reference line R1. Thereby, in the mounting substrate 104 of the first embodiment, the bending rigidity gently changes at the first reference line R1 as the boundary, as compared with the mounting substrate 54 of the comparative example.

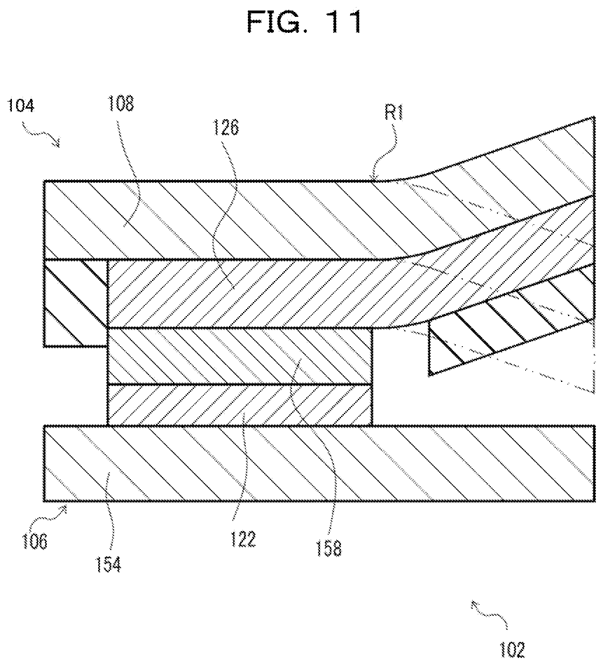

Therefore, the stress concentration at the position of the first reference line R1 in the case where the vibration in the plate thickness direction repeatedly acts on the mounting substrate 104 is relaxed. Then, in this case, as illustrated in FIG. 11, since the mounting substrate 104 is gently curved in the vicinity of the first reference line R1, the strain is dispersed as compared with the mounting substrate 54 of the comparative example, and the strain generated in the mounting substrate 104 is small. Then, since the strain is small, breakage (disconnection) of the wiring 156 due to fatigue can be suppressed. For example, in a case where an electronic device equipped with the substrate unit 102 is dropped from a high place, disconnection of the wiring 156 is suppressed even if vibration occurs in the mounting substrate 104 in the plate thickness direction due to the impact at the time of dropping, whereby the structure of the substrate unit 102 with high impact reliability can be implemented.

In the first embodiment, the abrupt change in the bending rigidity at the position of the first reference line R1 can be suppressed as long as the curved part 150 is provided in the first outer part 112P of the first land 116. In this respect, there is no limitation on the range of the radius of curvature r of the curved part 150. In practice, as will be described below, the range can be set to conditions that satisfy durability of not causing breakage of the wiring 156 in an impact drop test LESD22-B111 defined by JEDEC Solid State Technology Association (JEDEC).

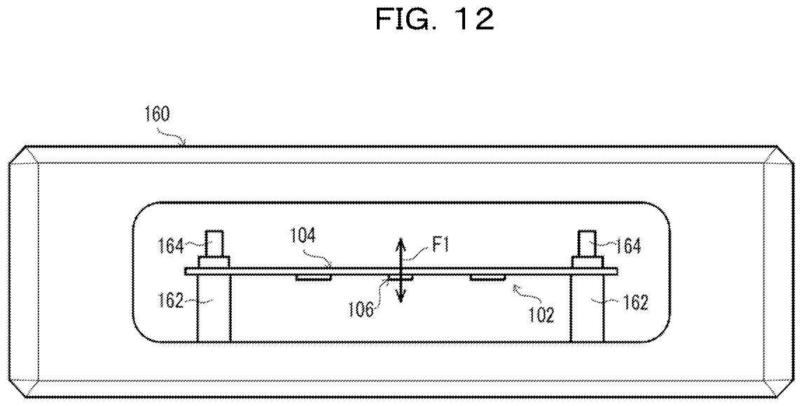

Specifically, as illustrated in FIG. 12, the substrate unit 102 is fixed at four points in the vicinity of the corners 110C of the mounting substrate 104 inside a test jig 160 having a predetermined shape. Note that FIG. 12 illustrates only two fixing bosses 162 and screws 164. Then, when the test jig 160 is dropped, vibration that the central portion of the substrate unit 102 is bent in the plate thickness direction as illustrated by the arrow F1 occurs by the impact of the drop.

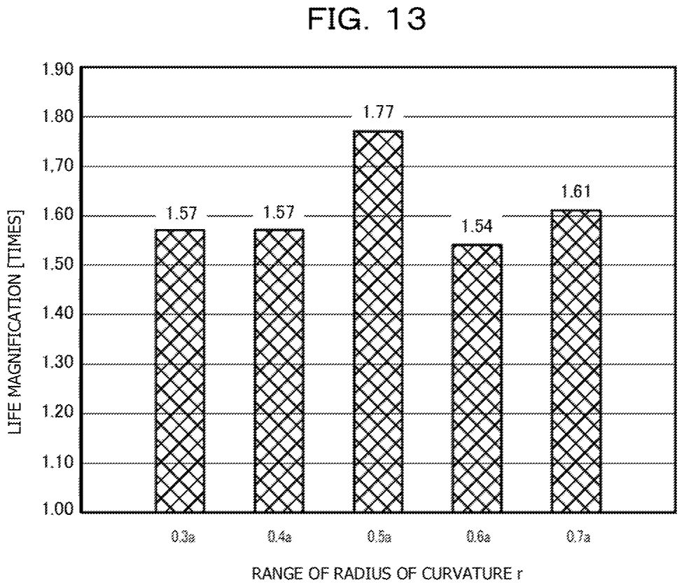

FIG. 13 illustrates a relationship between the radius of curvature r and life magnification in the case where the above drop impact test is performed. This life magnification is the magnification of the number of times until the wiring 156 is broken when a similar drop impact test is performed on the substrate unit of the comparative example.

As can be seen from FIG. 13, the lifetime magnification is the highest in the case of the radius of curvature of 0.5 a. Furthermore, the life magnification is 1.5 or more when the radius of curvature r is in a range of 0.3 a or larger and 0.7 a or smaller, and the effect of suppressing breakage (disconnection) due to fatigue of the wiring 156 is highly exhibited.

Note that, even if the radius of curvature r is less than 0.3 a or more than 0.7 a, the effect of suppressing the breakage (disconnection) due to fatigue of the wiring 156 is still exhibited.

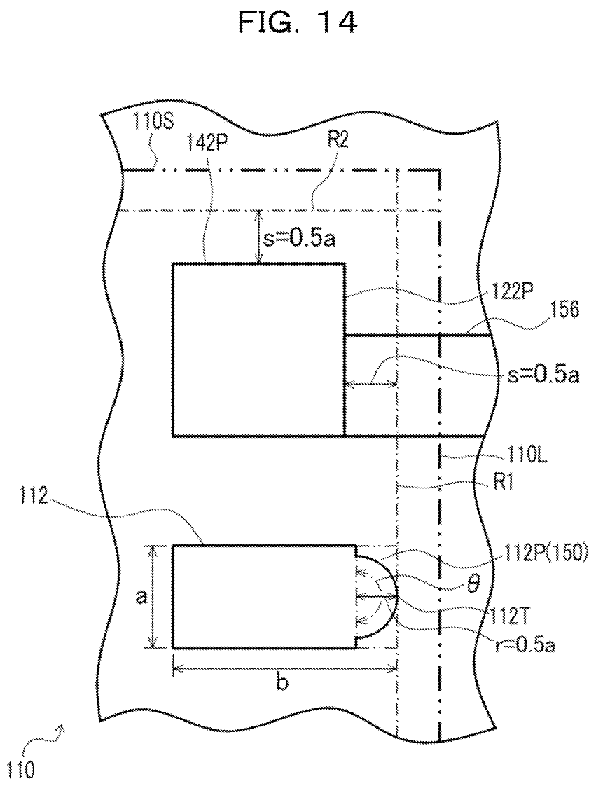

Here, FIG. 14 illustrates an example of the radius of curvature r=0.4 a of the curved part 150 as a first modification. In this structure, in the first land 116, straight portions 116M are present on both sides (upper and lower sides in FIG. 14) of the curved part 150. Even such a shape with the straight portions 116M has the effect of suppressing the breakage (disconnection) of the wiring 156 due to the action of impact.

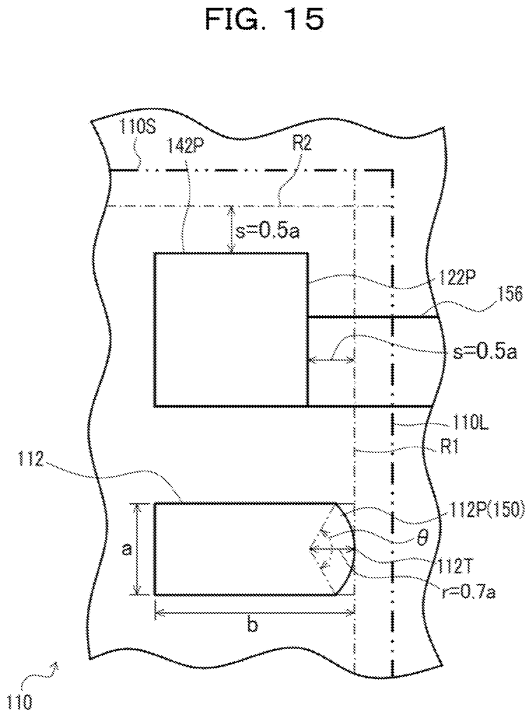

FIG. 15 illustrates an example of the radius of curvature r=0.7 a of the curved part 150 as a second modification. In this structure, the central angle 8 of the sector of the curved part 150 is smaller than 180 degrees. Then, compared with the structure illustrated in FIG. 6, the shape of the curved part 150 is closer to a straight line, but even such a shape close to a straight line still has the effect of suppressing breakage (disconnection) of the wiring 156 due to the action of impact.

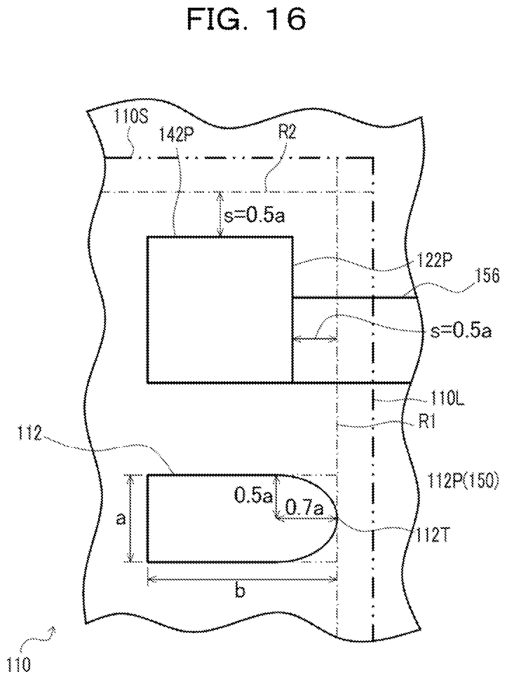

The radius of curvature r of the curved part 150 may not be fixed and change in one curved part 150. As a third modification, in the structure illustrated in FIG. 16, the curved part 150 has a half shape of an ellipse, specifically, a semi-elliptical shape with a major axis length of 1.4 a and a minor axis length of a. Even such a shape with the changed radius of curvature r of the curved part 150 has the effect of suppressing breakage (disconnection) of the wiring 156 due to the action of impact.

Note that, in contrast, the structure with the fixed radius of curvature r of the curved part 150 has simpler shapes of the first pad 112 and the first land 116 than the structure with the changed radius of curvature r and is easy to manufacture.

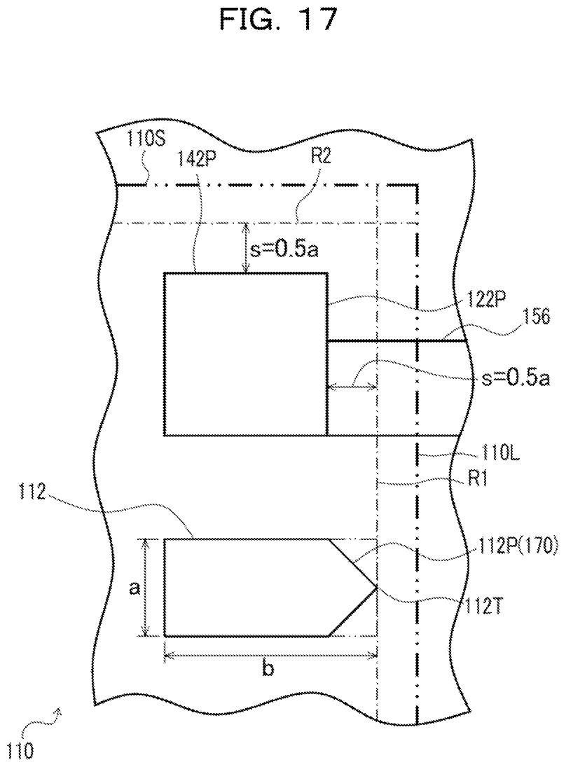

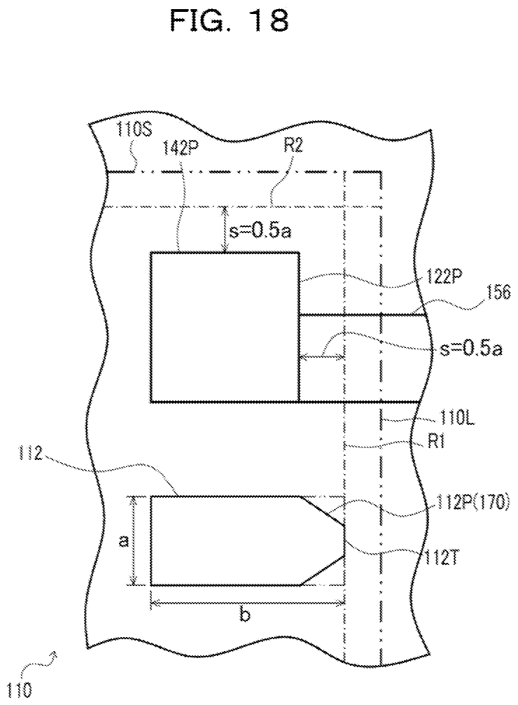

The above-described curved part 150 is an example of the inner displacement part. As the inner displacement part, structures of a fourth modification in FIG. 17 and a fifth modification in FIG. 18 can be adopted other than the above-described examples.

In both the structure of the fourth modification in FIG. 17 and the structure of the fifth modification in FIG. 18, inclined parts 170 with linearly chamfered corners are provided in the first outer part 112P of the first land 116. The fourth modification has a shape without a portion parallel to the first reference line R1 between the two inclined parts 170, whereas the fifth modification has a shape with a portion parallel to the first reference line R1 between the two inclined parts 170.

Both the structures of the fourth modification and the fifth modification have the effect of suppressing breakage (disconnection) of the wiring 156 due to the action of impact, as compared with the structure of the comparative example, for example.

In the structures of the first embodiment and the first to third modifications, the inner displacement part is the curved part 150 having the curved shape. By forming the inner displacement part into the curved shape in this manner, the structure in which the bending rigidity smoothly changes at the position of the first reference line R1 in the package substrate 110 and the mounting substrate 104 can be implemented.

Note that, in the first embodiment, the third pad 132 and the third land 136 are also provided with the curved part 150, as illustrated in FIGS. 3 and 5. The abrupt change in the bending rigidity at the position of the second reference line R2 is suppressed. Therefore, for example, in a case where the wiring extends in the direction along the long side 110L from the second land 126, the effect of suppressing breakage (disconnection) of the wiring can be exhibited for the curve in the arrow L1 direction.

Next, a second embodiment will be described. In the second embodiment, similar elements, members, and the like to those in the first embodiment are given the same reference numerals to those in the first embodiment, and detailed description thereof will be omitted.

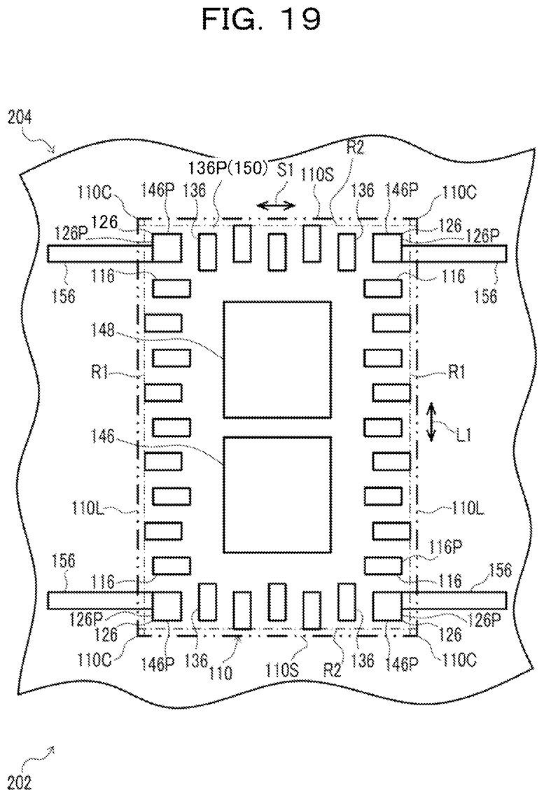

As illustrated in FIG. 19, in a substrate unit 202 of the second embodiment, a curved part 150 (see FIGS. 5, 6, 14 to 16 and the like) and inclined parts 170 (see FIGS. 17 and 18) are not formed in a first land 116 and a first outer part 112P is parallel to a first reference line

However, in some of a plurality of the first lands 116 arranged along one long side 110L, the first lands 116 themselves are provided at positions displaced inward. In the example illustrated in FIG. 19, nine first lands 116 arranged along the long side 110L are alternately located at positions displaced inward by a predetermined offset amount. Therefore, a structure in which some of the first outer parts 116P are provided with an inner displacement part located inside the first reference line R1 is implemented when considering the nine first lands 116 as a whole.

The second embodiment having such a structure has an effect of suppressing breakage (disconnection) of wiring 156 due to an action of impact, as compared with the structure of the comparative example.

In the above-described structures of the first embodiment and the first to fifth modifications, the positions of the first pad 112 and the first land 116 are not shifted in the arrow S1 direction. Therefore, for example, the influence on the portions other than the first pad 112 and the first land 116, for example, the influence on the shape of a circuit pattern and the like is small in the package substrate 110 and the mounting substrate 104.

The structures of the above-described first to fifth modifications and the second embodiment can be applied to the second pad 122 and the second land 126. When the structures of the above-described first to fifth modifications and the second embodiment are applied to the second pad 122 and the second land 126, the strain of the mounting substrate 104 can be suppressed with respect to the curvature of the mounting substrate 104 in the arrow L1 direction, for example.

In each of the above-described embodiments and modifications, the first pad 112 and the first land 116 have the same shape, and the second pad 122 and the second land 126 have the same shape, and the third pad 132 and the third land 136 have the same shape, when viewed in the normal direction. Therefore, it is possible to implement the state in which the pads and lands overlap each other without being displaced in the state where the LGA package 106 is mounted on the mounting substrate 104.

In each of the above embodiments and modifications, the LGA package 106 has the mold 154, and the mold 154 can protect the chip 152. The bending rigidity of the LGA package 106 is increased by having the mold 154, but even in this case, by adopting the structure of one of the above-described embodiments or modifications, the effect of suppressing breakage (disconnection) of the wiring 156 due to the action of impact can be exhibited.

While the embodiments of the technology disclosed in the present application have been described thus far, the technology disclosed in the present application is not limited to the above embodiments and, in addition to the above embodiments, of course may be carried out by making various modifications without departing from the spirit of the technology.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic device comprising:
a mounting substrate;
a package arranged facing the mounting substrate;
a plurality of first pads arranged on a facing surface facing the mounting substrate along a long side of the facing surface in the package;
a plurality of second pads arranged on the facing surface at respective corners of the facing surface;
a plurality of first lands provided on the mounting substrate and electrically bonded to the plurality of first pads, respectively facing the plurality of first pads; and
a plurality of second lands provided on the mounting substrate and electrically bonded to the plurality of second pads, respectively facing the plurality of second pads.

2. The electronic device according to claim 1, wherein
an inner displacement part partially located at an inside with respect to a reference line connecting ends of a plurality of first outer parts is provided in some of the plurality of first outer parts located on a side of the long side in the plurality of first lands; and
a second outer part located on the side of the long side is located at an inside with respect to the reference line in the second land.

3. The electronic device according to claim 2, wherein the inner displacement part is provided by partially locating each of the first outer parts at the inside in some or all of the plurality of first lands.

4. The electronic device according to claim 3, wherein the inner displacement part is a curved part obtained by curving each of the first outer parts.

5. The electronic device according to claim 4, wherein a radius of curvature r of the curved part is in a range of 0.3 a to 0.7 a, both inclusive, where a length in a direction along the long side is a in the first land.

6. The electronic device according to claim 5, wherein the radius of curvature r of the curved part is fixed.
